(19) United States
(12) Patent Application Publication
(10) Pub. No.: US 2024/0363697 A1
(43) Pub. Date: Oct. 31, 2024

(54) QUASI FIELD-PLATE STRUCTURE FOR SEMICONDUCTOR DEVICES

(71) Applicant: Taiwan Semiconductor Manufacturing Company, Ltd., Hsinchu (TW)

(72) Inventors: Yi-An Lai, Taipei City (TW); Chan-Hong Chern, Palo Alto, CA (US); Pen Chieh Yu, Hsinchu (TW); Cheng-Hsiang Hsieh, Taipei City (TW)

(21) Appl. No.: 18/351,784

(22) Filed: Jul. 13, 2023

Related U.S. Application Data
(60) Provisional application No. 63/498,315, filed on Apr. 26, 2023.

(51) Int. Cl. H01L 29/40; H01L 21/311; H01L 21/3213; H01L 29/06; H01L 29/205; H01L 29/417; H01L 29/423

(52) U.S. Cl. CPC H01L 29/405; H01L 21/31105; H01L 21/3213; H01L 29/0649; H01L 29/205; H01L 29/401; H01L 29/41775; H01L 29/42316; H01L 29/66431; H01L 29/7786

(57) ABSTRACT

Various embodiments of the present disclosure are directed towards a semiconductor device comprising a plurality of quasi field plates (QFPs) for enhanced wafer uniformity and performance. A channel layer and a barrier layer are stacked on a substrate, and the channel layer accommodates a two-dimensional carrier gas (2DCG). A source electrode, a drain electrode, and a gate electrode overlie the channel and barrier layers, and the gate electrode is between the source and drain electrodes in a first direction. The plurality of QFPs are between the gate electrode and the drain electrode. Further, the plurality of QFPs are capacitively or directly electrically coupled to the drain electrode, and are spaced from each other laterally in a line in a second direction transverse to the first direction.

### REFERENCE TO RELATED APPLICATION

This application claims the benefit of U.S. Provisional Application No. 63/498,315, filed on Apr. 26, 2023, the contents of which are incorporated by reference in their entirety.

### BACKGROUND

Semiconductor devices based on silicon have been the standard for the past few decades. However, semiconductor devices based on alternative materials are receiving increasing attention for advantages over silicon-based semiconductor devices. For example, semiconductor devices based on group III-V semiconductor materials have been receiving increased attention due to high breakdown voltages, high operating frequencies, and high electron mobilities compared to silicon-based semiconductor devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B illustrate various views of some embodiments of an integrated chip comprising a semiconductor device with a quasi field-plate (QFP) structure at a single level.

FIGS. 2A and 2B illustrate various views of some embodiments of the integrated chip of FIGS. 1A and 1B in which the semiconductor device further comprises a gate field plate (GFP) and a pair of source field plates (SFPs).

FIGS. 3A and 3B illustrate top layout views of some alternative embodiments of the integrated chip of FIGS. 2A and 2B.

FIGS. 4A-4C illustrate cross-sectional views of various alternative embodiments of the integrated chip of FIGS. 2A and 2B in which the QFP structure is at different levels.

FIGS. 5A-5C illustrate various views of some alternative embodiments of the integrated chip of FIGS. 2A and 2B in which the QFP structure spans multiple levels with overlapping QFPs.

FIGS. 6A-6G illustrate cross-sectional views of some alternative embodiments of the integrated chip of FIGS. 5A-5C.

FIGS. 7A-7C illustrate various views of some alternative embodiments of the integrated chip of FIGS. 2A and 2B in which the QFP structure spans multiple levels with non-overlapping QFPs.

FIGS. 8A-8C illustrate top layout views of some alternative embodiments of the integrated chip of FIGS. 7A-7C.

FIGS. 9A-9C illustrate various views of some alternative embodiments of the integrated chip of FIGS. 2A and 2B in which the QFP structure is electrically coupled directly to a drain electrode.

FIG. 10 illustrates a top layout view of some alternative embodiments of the integrated chip of FIGS. 9A-9C.

FIGS. 11A-11C illustrate various views of some alternative embodiments of the integrated chip of FIGS. 9A-9C in which the QFP structure is at a second level.

FIG. 12 illustrates a top layout view of some alternative embodiments of the integrated chip of FIGS. 11A-11C.

FIGS. 13A-13C illustrate various views of some alternative embodiments of the integrated chip of FIGS. 9A-9C in which the QFP structure is at a third level.

FIG. 14 illustrates a top layout view of some alternative embodiments of the integrated chip of FIGS. 13A-13C.

FIGS. 15A-15C illustrate various views of some alternative embodiments of the integrated chip of FIGS. 9A-9C in which the QFP structure is at a zeroth level.

FIG. 16 illustrates a top layout view of some alternative embodiments of the integrated chip of FIGS. 15A-15C.

FIGS. 17A-17C illustrate various views of some alternative embodiments of the integrated chip of FIGS. 9A-9C in which the QFP structure spans multiple levels with overlapping QFPs.

FIG. 18 illustrates a top layout view of some alternative embodiments of the integrated chip of FIGS. 17A-17C.

FIGS. 19A-19D illustrate various views of some alternative embodiments of the integrated chip of FIGS. 9A-9C in which the QFP structure spans multiple levels with non-overlapping QFPs.

FIG. 20 illustrates a top layout view of some alternative embodiments of the integrated chip of FIGS. 19A-19D.

FIGS. 21A-21C illustrate cross-sectional views of various alternative embodiments of the integrated chip of FIGS. 2A and 2B in which a GFP or a SFP is omitted.

FIGS. 22A and 22B illustrate various views of some alternative embodiments of the integrated chip of FIGS. 2A and 2B in which the semiconductor device is symmetrical.

FIGS. 23A-23C illustrate cross-sectional views of various alternative embodiments of the integrated chip of FIGS. 2A and 2B in which the integrated chip includes an etch stop layer.

FIGS. 24A and 24B to FIGS. 37A and 37B illustrate a series of views of some embodiments of a method for forming an integrated chip comprising a semiconductor device with a QFP structure.

FIG. 38 illustrates a block diagram of some embodiments of the method of FIGS. 24A and 24B to FIGS. 37A and 37B.

FIGS. 39A and 39B to FIGS. 42A and 42B illustrate a series of views of some alternative embodiments of the method of FIGS. 24A and 24B to FIGS. 37A and 37B in which the QFP structure is formed level with a cap structure.

FIGS. 43A and 43B to FIGS. 45A and 45B illustrate a series of views of some alternative embodiments of the method of FIGS. 24A and 24B to FIGS. 37A and 37B in which an isolation structure is formed before a cap structure.

FIGS. 46A and 46B to FIGS. 49A and 49B illustrate a series of views of some alternative embodiments of the method of FIGS. 24A and 24B to FIGS. 37A and 37B in which source and drain electrodes overlie an ILD layer.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A gallium nitride-on-silicon (e.g., GaN-on-Si) device may comprise a channel layer of gallium nitride (e.g., GaN) and a barrier layer of aluminum gallium nitride (e.g., AlGaN) stacked on a silicon substrate. The barrier layer overlies the channel layer and induces formation of a two-dimensional electron gas (2DEG) in the channel layer. Further, a source electrode, a drain electrode, and a gate electrode may overline the barrier layer with the gate electrode between the drain electrode and the source electrode.

The GaN-on-Si device may suffer from a tradeoff between breakdown voltage (e.g., V_{B}), ON resistance (e.g., R_{ON}), wafer uniformity, and reliability. For example, ON resistance may be decreased by increasing aluminum concentration of the barrier layer. However, this may decrease breakdown voltage, decrease reliability, and decrease wafer uniformity. As to wafer uniformity, increasing the aluminum concentration may lead to poor epitaxial growth of the channel and barrier layers. As such, performance parameters of the GaN-on-Si device may vary widely across a wafer on which the GaN-on-Si device is manufactured in bulk. Hence, wafer uniformity and manufacturing yields may decrease. As another example, breakdown voltage may be increased by decreasing the aluminum concentration. This may increase wafer uniformity and reliability. However, it may also increase ON resistance.

As an alternative to aluminum concentration, breakdown voltage may be increased through use of field plates. A maximum electric field (E-field) appears along a drain-side edge of the gate electrode and results in a low breakdown voltage and low reliability. The field plates use a reduced surface field (RESURF) technique to effectively increase a depletion region of the GaN-on-Si device and to therefore decrease the maximum E-field. Hence, the field plates increase breakdown voltage and increase reliability.

While the field plates may achieve increased breakdown voltage and reliability, the field plates have little effect on ON resistance and wafer uniformity may be poor. Wafer uniformity may, for example, be poor due to: 1) process variation forming the field plates; 2) epitaxial variation forming the channel and barrier layers; and 3) variation at a boundary of an active region on which the GaN-on-Si device is arranged. The boundary of the active region meets an isolation structure surrounding and demarcating the active region, which leads to high resistance and a non-uniform electric field that varies across a wafer.

Various embodiments of the present disclosure are directed to a semiconductor device (e.g., a GaN-on-Si device or the like) comprising a plurality of quasi field plates (QFPs). As described below, the plurality of QFPs may enhance wafer uniformity and performance of the semiconductor device. Such enhancement may, for example, be enhanced in terms of ON resistance, breakdown voltage, threshold voltage, OFF-state leakage, and so on. The plurality of QFPs may, for example, be more generally be referred to as field plates or the like.

In some embodiments, a channel layer and a barrier layer are stacked on a substrate, and the channel layer accommodates a two-dimensional carrier gas (2DCG). A source electrode, a drain electrode, and a gate electrode overlie the channel and barrier layers, and the gate electrode is between the source and drain electrodes in a first direction. The plurality of QFPs are between the gate electrode and the drain electrode. Further, the plurality of QFPs are electrically coupled (e.g., capacitively, directly, etc.) to the drain electrode, and are spaced from each other laterally in a line in a second direction transverse to the first direction.

During use of the semiconductor device, the plurality of QFPs attract carriers (e.g., electrons or holes) of a same type as carriers of the 2DCG. This increases conductivity of the 2DCG and has been appreciated to increase conductivity uniformity of the 2DCG. For example, QFPs may overlap with a junction between an active region on which the semiconductor device is arranged and an isolation structure surrounding and demarcating the active region. Absent overlapping QFPs, the 2DCG may have a low conductivity at the junction relative to surrounding regions of the 2DCG. However, the overlapping QFPs may attract carriers to increase conductivity at the junction so the conductivity at the junction better matches conductivity at the surrounding regions. Hence, conductivity uniformity may be increased.

Because the plurality of QFPs increase conductivity of the 2DCG, the plurality of QFPs reduce ON resistance. Because the plurality of QFPs increase conductivity uniformity, the plurality of QFPs increase electric field uniformity. Because electric field uniformity may be increased, threshold voltage and a peak electric field may be decreased. Because the peak electric field may be decreased, breakdown voltage and reliability may be increased and OFF-state leakage may be decreased. Because uniformity of the 2DCG and the electric field may be increased, wafer uniformity and manufacturing yields may be increased. It has been appreciated that this increase in wafer uniformity is sufficient to counteract any decrease in wafer uniformity from, for example, process variation, epitaxial variation, and the like.

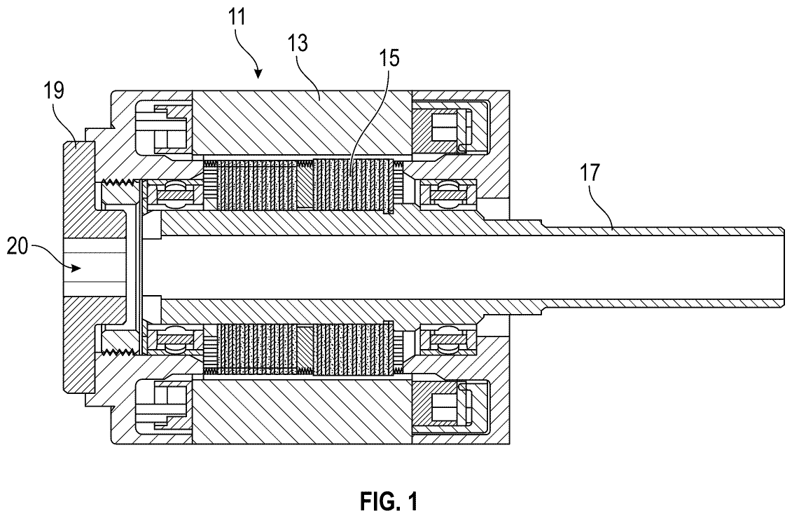

With reference to FIGS. 1A and 1B, various views 100A, 100B of some embodiments of an integrated chip comprising a semiconductor device 102 with a QFP structure 104 is provided. FIG. 1B corresponds to a top layout view 100B, whereas FIG. 1A corresponds to a cross-sectional view 100A along line A-A′ in FIG. 1B.

The semiconductor device 102 is on a semiconductor film 106 at an active region 106a of the semiconductor film 106, which is surrounded and demarcated by an isolation structure 108. The semiconductor film 106 accommodates a two-dimensional carrier gas (2DCG) 110, which forms a channel of the semiconductor device 102. The 2DCG 110 may, for example, be a 2DEG or a two-dimensional hole gas (2DHG). The semiconductor device 102 may, for example, be a GaN-on-Si device or the like and/or may, for example, be an enhancement mode high electron mobility transistor (E-HEMT) or the like. Other suitable device types are, however, amenable in alternative embodiments.

A source electrode 112 and a drain electrode 114 overlie the semiconductor film 106. In alternative embodiments, the source electrode 112 and the drain electrode 114 may be switched in location. Further, a cap structure 116 and a gate electrode 118 are stacked over the semiconductor film 106, laterally between the source electrode 112 and the drain electrode 114. The cap structure 116 is polarized so as to deplete the 2DCG 110 directly under the cap structure 116, thereby forming a depletion region 120.

The QFP structure 104 is laterally between the gate electrode 118 and the drain electrode 114. Further, the QFP structure 104 is spaced over the semiconductor film 106 at a first level, which is level with a top of the gate electrode 118. The QFP structure 104 is defined by or otherwise comprises a plurality of first-level QFPs 122₁₁. As such, the QFP structure 104 has a dot-type layout instead of a strip-type layout (e.g., a single large QFP). Compared to a strip-type layout, the dot-type layout may, for example, reduce parasitic capacitance to improve radio frequency (RF) performance of the semiconductor device 102.

The plurality of first-level QFPs 122₁₁ are capacitively coupled to surrounding structure, including the drain electrode 114, as schematically illustrated by capacitors 124. Further, as best seen in FIG. 1B, the plurality of first-level QFPs 122₁₁ are spaced in a line, which may also be referred to as a row or the like. The line extends in a first direction orthogonal to or otherwise transverse to a second direction along which the source electrode 112, the drain electrode 114, and the gate electrode 118 are spaced. In some embodiments, the line spans an entire width of the active region 106a, which extends in the first direction. The plurality of first-level QFPs 122₁₁ and hence the QFP structure 104 may more generally be referred to respectively as a plurality of first-level field plates and a field-plate structure.

During use of the semiconductor device 102, the QFP structure 104 is biased with a voltage that is proportional to a voltage at the drain electrode 114 via capacitive coupling (see, e.g., the capacitors 124) between the QFP structure 104 and the drain electrode 114. In alternative embodiments, the QFP structure 104 is directly electrically coupled to the drain electrode 114. The biasing attracts carriers 125 of a same type as carriers of the 2DCG 110 to the 2DCG 110. For example, when the 2DCG 110 is a 2DEG, the QFP structure 104 attracts electrons. As another example, when the 2DCG 110 is a 2DHG, the QFP structure 104 attracts holes. The attracted carriers 125 increase conductivity of the 2DCG 110 and have been appreciated to increase conductivity uniformity of the 2DCG 110.

As an example, attention is directed to FIG. 1B. The 2DCG 110 may have a lower conductivity at a junction 126 between the active region 106a and the isolation structure 108 than at surrounding regions of the 2DCG 110. By arranging QFPs of the QFP structure 104 (e.g., QFPs at ends of the line) overlapping with the junction 126, conductivity of the 2DCG 110 may be increased at the junction 126 and may more closely match the conductivity of the 2DCG 110 at the surrounding regions. Hence, conductivity uniformity may be increased.

Because the QFP structure 104 increases conductivity of the 2DCG 110, the QFP structure 104 reduces ON resistance of the semiconductor device 102. Because the QFP structure 104 increases conductivity uniformity, the QFP structure 104 increases electric field uniformity of the semiconductor device 102. Because electric field uniformity may be increased, threshold voltage and a peak electric field may be decreased. Because the peak electric field may be decreased, breakdown voltage and reliability may be increased and OFF-state leakage may be decreased. Because uniformity of the 2DCG 110 and the electric field may be increased, wafer uniformity and manufacturing yields may be increased. It has been appreciated that this increase in wafer uniformity may be sufficient to counteract any decrease in wafer uniformity from, for example, process variation, epitaxial variation, and the like.

Because the QFP structure 104 is level with the gate electrode 118, the QFP structure 104 may be formed concurrently with the gate electrode 118. As such, costs for forming the QFP structure 104 may be small. Further, because the QFP structure 104 spans a relatively small area, the QFP structure 104 may not increase a size of the semiconductor device 102.

In some embodiments, the plurality of first-level QFPs 122₁₁ are or comprises nickel, gold, platinum, iridium, titanium nitride, aluminum copper, palladium, some other suitable metal(s) and/or metallic material(s), or any combination of the foregoing. While the QFP structure 104 is illustrated with seven QFPs, the QFP structure 104 may alternatively have about 10-1000 QFPs, about 10-505 QFPs, about 505-1000 QFPs, or some other suitable number of QFPs. For example, the QFP structure 104 may alternatively have 10 or 100 QFPs. It has been appreciated that multiple small QFPs in a line, instead of a single large QFP, is more effective at enhancing performance and wafer uniformity of the semiconductor device 102.

Focusing on FIG. 1B, the plurality of first-level QFPs 122₁₁ are separated from the drain electrode 114 by a first separation S1 and are separated from each other by a second separation S2. The first separation S1 may, for example, be about 0.5-5 micrometers, about 0.5-2.75 micrometers, about 2.75-5 micrometers, about 3 micrometers, about 5 micrometers, or some other suitable value. The second separation S2 may, for example, be about 0.5-5 micrometers, about 0.5-2.75 micrometers, about 2.75-5 micrometers, about 0.5 micrometers, or some other suitable value. In some embodiments, the first separation S1 and/or the second separation S2 is/are about 0.5 micrometers. Other suitable values are, however, amenable.

The first separation S1 is small enough to allow capacitive coupling between the plurality of first-level QFPs 122₁₁ and the drain electrode 114, such that a first voltage Vₙ at the plurality of first-level QFPs 122₁₁ is proportional to a second voltage V_{d} at the drain electrode 114. In some embodiments, the first voltage Vₙ is related to the second voltage V_{d} by Vₙ=jwRCV_{d}, where w is the angular frequency, R is a resistance from the QFP structure 104 to ground, and C is capacitance from the QFP structure 104 to the drain electrode 114. If the first separation S1 is too large (e.g., greater than about 5 micrometers or some other suitable value), capacitive coupling between the plurality of first-level QFPs 122₁₁ and the drain electrode 114 may be effectively zero. As a result, the QFP structure 104 may be ineffective at enhancing performance and/or wafer uniformity of the semiconductor device 102.

The plurality of first-level QFPs 122₁₁ have a first dimension D1 and a second dimension D2 orthogonal to the first dimension D1. The first dimension D1 and/or the second dimension D2 may, for example, be about 0.25-10 micrometers, about 0.25-5.125 micrometers, about 5.125-10 micrometers, about 0.5 micrometers, or some other suitable value. In some embodiments, the first dimension D1 and the second dimension D2 are 0.5 micrometers. In some embodiments, the first dimension D1 is 1 micrometer and the second dimension D2 is 2 micrometers or vice versa. Other suitable values are, however, amenable.

Focusing on FIG. 1A, the gate electrode 118 is closer to the source electrode 112 than to the drain electrode 114 to enhance breakdown voltage and/or reduce leakage. During use of the semiconductor device 102, the gate electrode 118 is selectively biased to generate an electric field that manipulates a continuity of the 2DCG 110 from the source electrode 112 to the drain electrode 114. For example, when the gate electrode 118 is biased with a voltage that is more than a threshold voltage, the gate electrode 118 may attract carriers (e.g., electrons or holes) of a same type as carriers of the 2DCG 110. As a result, the 2DCG 110 may be continuous from the the source electrode 112 to the drain electrode 114.

The semiconductor film 106 comprises a channel layer 128, a barrier layer 130, and a buffer layer 132. The channel layer 128 has a different bandgap than the barrier layer 130 and underlies and directly contacts the barrier layer 130 at a heterojunction. Hence, the channel layer 128 and the barrier layer 130 form a heterojunction structure (e.g., a group III-V heterojunction structure or some other suitable type of heterojunction structure). Further, the channel layer 128 is spaced from the source and drain electrodes 112, 114 by the barrier layer 130 and accommodates the 2DCG 110. The 2DCG 110 extends along the heterojunction and has a high concentration of mobile carriers. Because of the high concentration, the 2DCG 110 is conductive. The 2DCG 110 may, for example, be a 2DEG or a 2DHG.

The barrier layer 130 is polarized so the 2DCG 110 forms in the channel layer 128. For example, the barrier layer 130 may be polarized so positive charge is shifted towards a bottom surface of the barrier layer 130, and negative charge is shifted towards a top surface of the barrier layer 130, to form the 2DCG 110 as a 2DEG. The polarization may, for example, result from spontaneous and/or piezoelectric polarization effects.

Similar to the barrier layer 130, the cap structure 116 is polarized so as to deplete the 2DCG 110 directly under the cap structure 116. As such, the depletion region 120 forms in the absence of an electric field from the gate electrode 118. Further, the cap structure 116 has a bandgap unequal to a bandgap of the barrier layer 130.

The buffer layer 132 separates the channel and barrier layers 128, 130 from a substrate 134 underlying the semiconductor film 106. Further, the buffer layer 132 buffers and/or transitions between differences in lattice constants, crystalline structures, thermal expansion coefficients, other suitable parameters, or any combination of the foregoing from the substrate 134 to the channel layer 128. By buffering and/or transitioning between such differences, crystalline quality of the channel and barrier layers 128, 130 may be high and/or stress on the channel and barrier layers 128, 130 may be low. This may, for example, enhance performance and/or reduce failure of the semiconductor device 102.

An interconnect structure 136 overlies and electrically couples to the semiconductor device 102. The interconnect structure 136 comprises a plurality of wires 138 and a plurality of vias 140 stacked in an interconnect dielectric layer 142. In some embodiments, the plurality of wires 138 and/or the plurality of vias 140 are or comprise aluminum copper, copper, tungsten, some other suitable materials, or any combination of the foregoing. In some embodiments, the interconnect dielectric layer 142 completely surrounds the QFP structure 104.

In some embodiments, the semiconductor film 106 is or comprises group III-V semiconductor materials, group II-VI semiconductor materials, or the like. In other embodiments, the semiconductor film 106 is or comprises some other suitable semiconductor materials suitable for forming the 2DCG 110.

In some embodiments, the channel layer 128 is or comprises gallium nitride (e.g., GaN), gallium arsenide (e.g., GaAs), indium phosphide (e.g., InP), some other suitable group III-V material(s), or any combination of the foregoing. In some embodiments, the channel layer 128 is or comprises a binary group III-V material and/or comprises the same elements as the buffer layer 132. For example, the channel layer 128 and the buffer layer 132 may comprise gallium nitride. In some embodiments, the channel layer 128 is undoped.

In some embodiments, the cap structure 116 is or comprises gallium nitride, some other suitable group III nitride, or some other suitable group III-V material. In some embodiments, the cap structure 116 is or comprises a binary group III-V material and/or comprises the same elements as the channel layer 128. In some embodiments, the cap structure 116 is doped with, for example, p-type or n-type dopants.

In some embodiments, the barrier layer 130 is or comprises aluminum gallium nitride (e.g., AlGaN), indium aluminum nitride (e.g., InAlN), aluminum nitride (e.g., AlN), aluminum gallium arsenide (e.g., AlGaAs), indium aluminum arsenide (e.g., InAlAs), indium gallium arsenide (e.g., InGaAs), some other suitable group III-V material(s), or any combination of the foregoing. In some embodiments, the barrier layer 130 is or comprises a ternary group III-V material and/or is undoped. In some embodiments, the barrier layer 130 is aluminum gallium nitride and the channel layer 128 is gallium nitride.

In some embodiments, the channel layer 128 is or comprises gallium nitride, the barrier layer 130 is or comprises aluminum gallium nitride, and the cap structure 116 is or comprises p-doped gallium nitride. Other suitable materials are, however, amenable. In some embodiments, the buffer layer 132 is or comprises gallium nitride (e.g., GaN), gallium arsenide (e.g., GaAs), indium phosphide (e.g., InP), aluminum nitride (e.g., AlN), aluminum gallium nitride (e.g., AlGaN), carbon-doped gallium nitride (e.g., GaN:C), some other suitable group III-V material(s), or any combination of the foregoing.

In some embodiments, the substrate 134 is or comprises silicon, sapphire, some other suitable crystalline material, or any combination of the foregoing. In at least some embodiments in which the semiconductor film 106 is or comprises group III-V materials, the substrate 134 is devoid of group III-V semiconductor materials. In some embodiments, the substrate 134 is a bulk semiconductor substrate and/or is a semiconductor wafer.

In some embodiments, the source electrode 112 and the drain electrode 114 are ohmically coupled to the 2DCG 110. In some embodiments, the source electrode 112 and the drain electrode 114 are or comprise titanium, aluminum, nickel, gold, some other suitable metal(s), or any combination of the foregoing. In some embodiments, the gate electrode 118 is or comprises nickel, gold, platinum, iridium, titanium nitride, aluminum copper, palladium, some other suitable metal(s) and/or metallic material(s), or any combination of the foregoing.

In some embodiments, the isolation structure 108 is an oxidized portion of the channel layer 128 and the barrier layer 130 and/or an oxygen rich portion of the channel layer 128 and the barrier layer 130. In other embodiments, the isolation structure 108 is a trench isolation structure comprising a dielectric material. For example, the isolation structure 108 may be or comprise a shallow trench isolation (STI) structure or the like.

As used above and hereafter, reference may be made to two elements, A and B, being level with each other. “A level with B” or like should be understood to mean that a top of A is at a same height or elevation as a top of B, a bottom of A is at a same height or elevation as a bottom of B, or a portion of A is at a same height or elevation as a portion of B. “A” generically refers to an element, and “B” generically refers to another element.

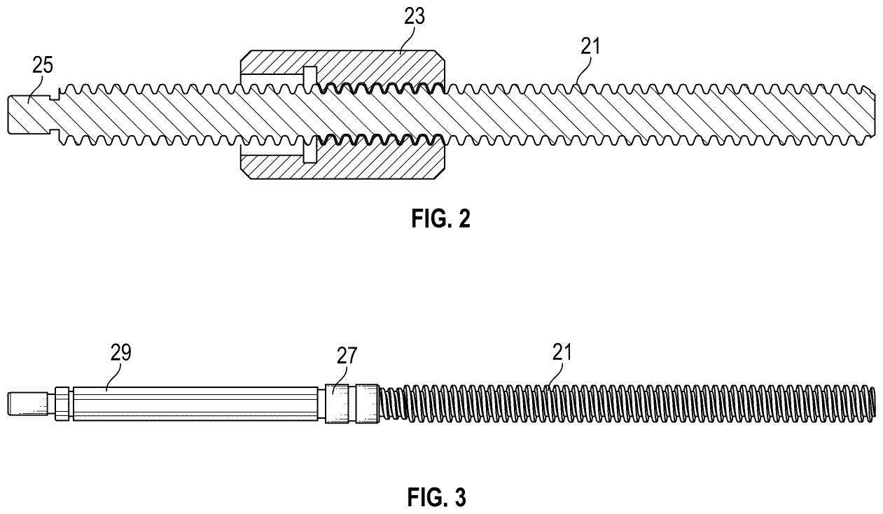

With reference to FIGS. 2A and 2B, various views 200A, 200B of some embodiments of the integrated chip of FIGS. 1A and 1B are provided in which the semiconductor device 102 comprises a gate field plate (GFP) 202, a first source field plate (SFP) 204, and a second SFP 206. Further, the buffer layer 132 and the interconnect dielectric layer 142 are shown in greater detail compared to FIGS. 1A and 1B. FIG. 2B corresponds to a top layout view 200B, whereas FIG. 2A corresponds to a cross-sectional view 200A along line A-A′ in FIG. 2B.

An interlayer dielectric (ILD) 208, a first IMD layer 210, and a second IMD layer 212 are stacked over the semiconductor film 106 and correspond to the interconnect dielectric layer 142 of FIGS. 1A and 1B. The first IMD layer 210 overlies the ILD layer 208, and the second IMD layer 212 overlies the first IMD layer 210.

The source electrode 112 and the drain electrode 114 are covered by the ILD layer 208, and the gate electrode 118 and the cap structure 116 form a gate stack extending through the ILD layer 208. The GFP 202 and the QFP structure 104 overlie the ILD layer 208, between the ILD layer 208 and the first IMD layer 210, and are level with each other at a first level. As such, the GFP 202 and the QFP structure 104 may, for example, be formed together to reduce manufacturing costs. The GFP 202 is integrated with the gate electrode 118 and protrudes from a top of the gate electrode 118 towards the drain electrode 114. The QFP structure 104 is between the GFP 202 and the drain electrode 114.

The first SFP 204 overlies the GFP 202 and the first IMD layer 210, between the first IMD layer 210 and the second IMD layer 212. Further, the first SFP 204 is electrically coupled to the source electrode 112 via the interconnect structure 136. The first SFP 204 has a drain-side edge that is closer to the drain electrode 114 than a drain-side edge of the GFP 202 in a dimension along which the source electrode 112 and the drain electrode 114 are spaced from each other (e.g., the left-right dimension in FIG. 2A). In some embodiments, the first SFP 204 is or comprises titanium nitride, some other suitable metal nitride, some other suitable conductive material, or any combination of the foregoing.

The second SFP 206 overlies the first SFP 204 and the second IMD layer 212 and is electrically coupled to the source electrode 112 via the interconnect structure 136. Further, the second SFP 206 is integrated into one of the plurality of wires 138. The second SFP 206 has a drain-side edge that is closer to the drain electrode 114 than a drain-side edge of the first SFP 204 in the dimension along which the source electrode 112 and the drain electrode 114 are spaced from each other (e.g., the left-right dimension in FIG. 2A).

During operation of the semiconductor device 102, the GFP 202, the first SFP 204, and the second SFP 206 use a RESURF technique to effectively increase the depletion region 120 and to decrease the maximum E-field. This, in turn, increases breakdown voltage and reliability. Further, the GFP 202, the first SFP 204, and the second SFP 206 are biased respectively with a voltage at the gate electrode 118 and a voltage at the source electrode 112. In contrast, the QFP structure 104 is biased directly with a voltage at the drain electrode 114 or indirectly with a voltage that is proportional to the voltage at the drain electrode 114. Hence, the QFP structure 104 is distinguished from the GFP 202, the first SFP 204, and the second SFP 206 by referring to it as a “quasi” field-plate structure. However, the QFP structure 104 and the plurality of first-level QFPs 122₁₁ may more generally be referred to respectively as a field-plate structure and a plurality of first-level field plates.

A buffer nucleation layer 214, a graded buffer layer 216, a super lattice buffer layer 218, and a high resistivity buffer layer 220 are stacked between the substrate 134 and the channel layer 128. These layers may, for example, correspond to the buffer layer 132 of FIGS. 1A and 1B. In alternative embodiments, the buffer nucleation layer 214, the graded buffer layer 216, the super lattice buffer layer 218, the high resistivity buffer layer 220, or any combination of the foregoing is/are omitted. In alternative embodiments, one or more additional buffer layers are between the substrate 134 and the channel layer 128.

The buffer nucleation layer 214 facilitates nucleation of the graded buffer layer 216 during epitaxial deposition. The graded buffer layer 216 overlies the buffer nucleation layer 214 and includes a first metal element and a second metal element. The first metal element decreases from a bottom of the graded buffer layer 216 to a top of the graded buffer layer 216, and the second metal element increases from the bottom of the graded buffer layer 216 to the top of the graded buffer layer 216. In some embodiments, the first metal element is in the buffer nucleation layer 214, and/or the second metal element is in the channel layer 128.

The super lattice buffer layer 218 overlies the graded buffer layer 216 and comprises an alternating stack of layers that may, for example, release stress (e.g., tensile stress) of the high resistivity buffer layer 220. The super lattice buffer layer 218 comprises an alternating stack of first material layers and second material layers. The first material layers may, for example, be or comprise a same material as the buffer nucleation layer 214, and/or the second material layers may, for example, be or comprise a same material as the channel layer 128. Other suitable materials are, however, amenable in alternative embodiments.

The high resistivity buffer layer 220 overlies the super lattice buffer layer 218. The high resistivity buffer layer 220 is a same material as the channel layer 128, but is highly doped with carbon, iron, or the like so as to have a high resistance relative to the channel layer 128. As a result of the high resistance, the high resistivity buffer layer 220 acts as a back barrier for the channel layer 128 to increase breakdown voltage.

In some embodiments, the buffer nucleation layer 214 is or comprise aluminum nitride (e.g., AlN), the graded buffer layer 216 is or comprises aluminum gallium nitride (e.g., AlGaN) with graded aluminum and gallium, the super lattice buffer layer 218 is or comprises an alternating stack of aluminum nitride (e.g., AlN) and gallium nitride (e.g., GaN), the high resistivity buffer layer 220 is or comprises carbon or iron doped gallium nitride (e.g., GaN:C or GaN:Fe), the channel layer 128 is or comprises undoped gallium nitride (e.g., u-GaN), the barrier layer 130 is or comprises aluminum gallium nitride (e.g., AlGaN), and the cap structure 116 is or comprises p-doped gallium nitride (e.g., p-GaN). Other suitable materials for any one or combination of the foregoing layers and structures is/are, however, amenable.

With reference to FIGS. 3A and 3B, top layout views 300A, 300B of some alternative embodiments of the integrated chip of FIGS. 2A and 2B are provided. In FIG. 3A, the source electrode 112 and the drain electrode 114 are localized to the active region 106a. As such, the source electrode 112 and the drain electrode 114 do not overlap with the isolation structure 108. In FIG. 3B, the plurality of first-level QFPs 122₁₁ have individual top geometries that are circle shaped instead of square shaped. The circle shape may, for example, reduce high electric fields because it does not have corners found in, for example, polygonal shapes. Hence, the circle shape may allow the semiconductor device 102 to sustain higher voltage stress. In alternative embodiments, the individual top geometries may have some other suitable shape.

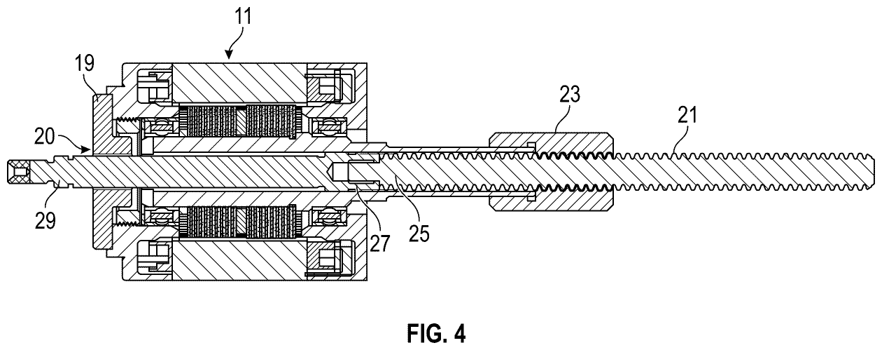

With reference to FIGS. 4A-4C, cross-sectional views 400A-400C of some alternative embodiments of the integrated chip of FIGS. 2A and 2B are provided in which the QFP structure 104 is at different levels.

In FIG. 4A, the QFP structure 104 is at a second level overlying the first IMD layer 210, between the first IMD layer 210 and the second IMD layer 212. Hence, the QFP structure 104 is level with the first SFP 204 and may, for example, be formed with the first SFP 204 to reduce manufacturing costs. The QFP structure 104 is defined by or otherwise comprises a plurality of second-level QFPs 122₁₂ in place of the plurality of first-level QFPs 122₁₁. The plurality of second-level QFPs 122₁₂ are as the plurality of first-level QFPs 122₁₁ are described above other than being at a different level and, in some embodiments, a different material. In some embodiments, the plurality of second-level QFPs 122₁₂ are or comprise a same material as the first SFP 204 and/or are or comprise titanium nitride, some other suitable metal nitride or conductive material, or any combination of the foregoing. Further, in some embodiments, the plurality of second-level QFPs 122₁₂ and hence the QFP structure 104 are more generally referred to respectively as a plurality of second-level field plates and a field-plate structure.

In FIG. 4B, the QFP structure 104 is at third level overlying the second IMD layer 212. Hence, the QFP structure 104 is level with the second SFP 206 and may, for example, be formed with the second SFP 206 to reduce manufacturing costs. The QFP structure 104 comprises a plurality of third-level QFPs 122₁₃ in place of the plurality of first-level QFPs 122₁₁. The plurality of third-level QFPs 122₁₃ are as the plurality of first-level QFPs 122₁₁ are described above other than being at a different level and, in some embodiments, a different material. In some embodiments, the plurality of third-level QFPs 122₁₃ are or comprise a same material as the second SFP 206 and/or are or comprise aluminum, aluminum copper, copper, some other conductive material, or any combination of the foregoing. Further, in some embodiments, the plurality of third-level QFPs 122₁₃ and hence the QFP structure 104 are more generally referred to respectively as a plurality of third-level field plates and a field-plate structure.

In FIG. 4C, the QFP structure 104 is at zeroth level underlying the ILD layer 208, between the ILD layer 208 and the barrier layer 130. Hence, the QFP structure 104 is level with the cap structure 116, the source electrode 112, and the drain electrode 114. The QFP structure 104 comprises a plurality of zeroth-level QFPs 122₁₀ in place of the plurality of first-level QFPs 122₁₁. The plurality of zeroth-level QFPs 122₁₀ are as the plurality of first-level QFPs 122₁₁ are described above other than being at a different level and, in some embodiments, a different material. In some embodiments, the plurality of zeroth-level QFPs 122₁₀ are or comprise a same material as the first SFP 204 and/or are or comprise titanium nitride, some other suitable metal nitride or conductive material, or any combination of the foregoing. Further, in some embodiments, the plurality of zeroth-level QFPs 122₁₀ and hence the QFP structure 104 are more generally referred to respectively as a plurality of zeroth-level field plates and a field-plate structure.

With reference to FIGS. 5A-5C, various views 500A-500C of some alternative embodiments of the integrated chip of FIGS. 2A and 2B are provided in which the QFP structure 104 spans multiple levels with overlapping QFPs. FIG. 5C corresponds to a top layout view 500C, whereas FIG. 5A corresponds to a cross-sectional view 500A along line A-A′ in FIG. 5C and FIG. 5B corresponds to a cross-sectional view 500B along line B-B′ in FIG. 5C. The multiple levels include the first level as illustrated by, for example, FIGS. 1A to 2B and the second level as illustrated by, for example, FIG. 4A.

The QFP structure 104 comprises a plurality of first-level QFPs 122₁₁ and a plurality of second-level QFPs 122₁₂ grouped into a plurality of QFP groups 502. The plurality of QFP groups 502 are spaced in a line extending orthogonal to or otherwise transverse to a direction along which the source electrode 112, the drain electrode 114, and the gate electrode 118 are spaced. Further, each of the plurality of QFP groups 502 comprises one of the plurality of first-level QFPs 122₁₁ and one of the plurality of second-level QFPs 122₁₂ overlapping the one of the plurality of first-level QFPs 122₁₁. The plurality of first-level QFPs 122₁₁ and the plurality of second-level QFPs 122₁₂ are as described above.

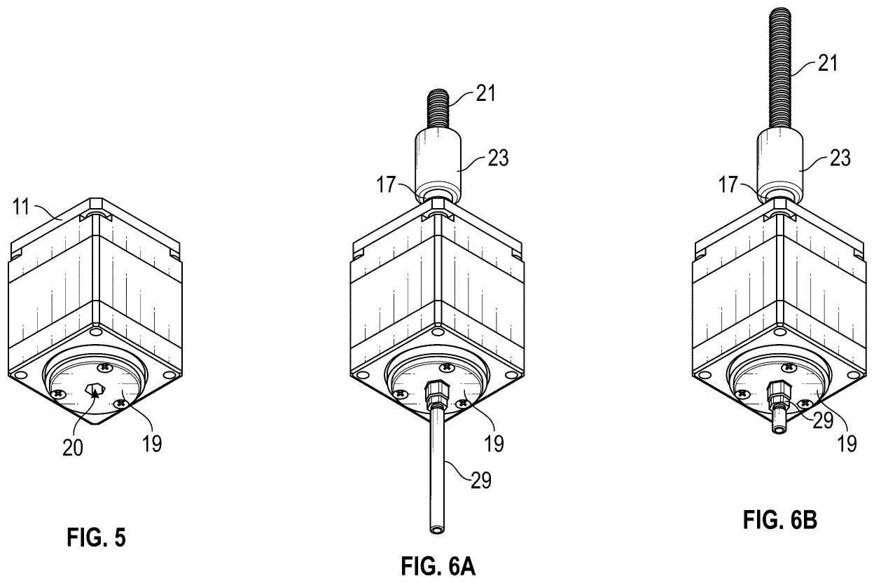

With reference to FIGS. 6A-6G, cross-sectional views 600A-600G of some alternative embodiments of the integrated chip of FIGS. 5A-5C are provided. The cross-sectional views 600A-600G of FIGS. 6A-6G correspond to the cross-sectional view 500B of FIG. 5B and hence correspond to line B-B′ in FIG. 5C.

In FIG. 6A, the QFP structure 104 comprises a plurality of zeroth-level QFPs 122₁₀ in place of the plurality of second-level QFPs 122₁₂. As such, each of the plurality of QFP groups 502 comprises one of the plurality of zeroth-level QFPs 122₁₀ and one of the plurality of first-level QFPs 122₁₁ overlapping the one of the plurality of zeroth-level QFPs 122₁₀.

In FIG. 6B, the QFP structure 104 comprises a plurality of third-level QFPs 122₁₃ in place of the plurality of second-level QFPs 122₁₂. As such, each of the plurality of QFP groups 502 comprises one of the plurality of first-level QFPs 122₁₁ and one of the plurality of third-level QFPs 122₁₃ overlapping the one of the plurality of first-level QFPs 122₁₁.

In FIG. 6C, the QFP structure 104 further comprises a plurality of zeroth-level QFPs 122₁₀ forming the plurality of QFP groups 502. As such, each of the plurality of QFP groups 502 comprises: one of the plurality of zeroth-level QFPs 122₁₀; one of the plurality of first-level QFPs 122₁₁ overlapping the one of the plurality of zeroth-level QFPs 122₁₀; and one of the plurality of second-level QFPs 122₁₂ overlapping the one of the plurality of first-level QFPs 122₁₁.

In FIG. 6D, the QFP structure 104 further comprises a plurality of zeroth-level QFPs 122₁₀ forming the plurality of QFP groups 502. Further, the QFP structure 104 comprises a plurality of third-level QFPs 122₁₃ in place of the plurality of first-level QFPs 122₁₁. As such, each of the plurality of QFP groups 502 comprises: one of the plurality of zeroth-level QFPs 122₁₀; one of the plurality of second-level QFPs 122₁₂ overlapping the one of the plurality of zeroth-level QFPs 122₁₀; and one of the plurality of third-level QFPs 122₁₃ overlapping the one of the plurality of second-level QFPs 122₁₂.

In FIG. 6E, the QFP structure 104 further comprises a plurality of zeroth-level QFPs 122₁₀ and a plurality of third-level QFPs 122₁₃ forming the plurality of QFP groups 502. As such, each of the plurality of QFP groups 502 comprises: one of the plurality of zeroth-level QFPs 122₁₀; one of the plurality of first-level QFPs 122₁₁ overlapping the one of the plurality of zeroth-level QFPs 122₁₀; one of the plurality of second-level QFPs 122₁₂ overlapping the one of the plurality of first-level QFPs 122₁₁; and one of the plurality of third-level QFPs 122₁₃ overlapping the one of the plurality of second-level QFPs 122₁₂.

In FIG. 6F, the QFP structure 104 further comprises a plurality of zeroth-level QFPs 122₁₀ forming a plurality of additional QFP groups 602. The plurality of additional QFP groups 602 alternate with the plurality of QFP groups 502 and each comprises: one of the plurality of zeroth-level QFPs 122₁₀; and one of the plurality of first-level QFPs 122₁₁ overlapping the one of the plurality of zeroth-level QFPs 122₁₀.

In FIG. 6G, the plurality of QFP groups 502 are spaced and alternate with individual ones of the plurality of first-level QFPs 122₁₁ in the line.

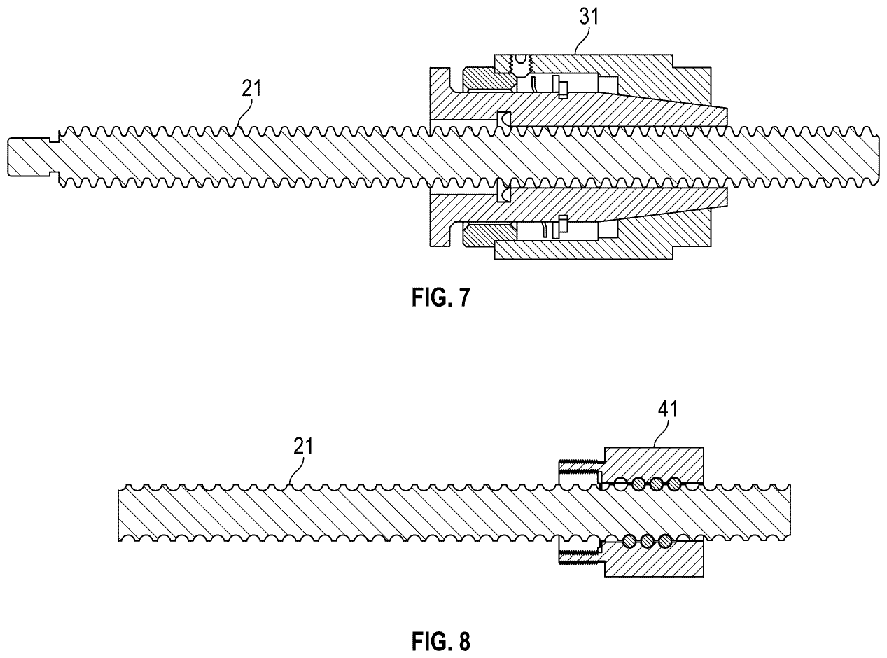

With reference to FIGS. 7A-7C, various views 700A-700C of some alternative embodiments of the integrated chip of FIGS. 2A and 2B are provided in which the QFP structure spans multiple levels with non-overlapping QFPs. FIG. 7C corresponds to a top layout view 700C, whereas FIG. 7A corresponds to a cross-sectional view 700A along line A-A′ in FIG. 7C and FIG. 7B corresponds to a cross-sectional view 700B along line C-C′ in FIG. 7C.

The QFP structure 104 comprises a plurality of first-level QFPs 122₁₁ and a plurality of second-level QFPs 122₁₂. The plurality of first-level QFPs 122₁₁ overlap with the junction 126 between the active region 106a and the isolation structure 108 at ends of the line defined by QFPs of the QFP structure 104. The plurality of second-level QFPs 122₁₂ fill in a remainder of the QFP structure 104 between the ends of the line defined by the QFPs of the QFP structure 104.

With reference to FIGS. 8A-8C, top layout views 800A-800C of some alternative embodiments of the integrated chip of FIGS. 7A-7C are provided. In FIG. 8A, the plurality of first-level QFPs 122₁₁ and the plurality of second-level QFPs 122₁₂ alternate from end to end of the line defined by the QFPs of the QFP structure 104. In FIG. 8B, the plurality of first-level QFPs 122₁₁ are replaced with a plurality of zeroth-level QFPs 122₁₀ (see, e.g., FIG. 4C). In FIG. 8C, the plurality of second-level QFPs 122₁₂ are replaced with a plurality of third-level QFPs 122₁₃ (see, e.g., FIG. 4B).

While FIGS. 5A-5C and 6A-6G illustrate various combinations of first-level QFPs 122₁₁, second-level QFPs 122₁₂, third-level QFPs 122₁₃, and zeroth-level QFPs 122₁₀, any other combination is amenable. Similarly, while FIGS. 7A-7C and 8A-8C illustrate various combinations of first-level QFPs 122₁₁, second-level QFPs 122₁₂, third-level QFPs 122₁₃, and zeroth-level QFPs 122₁₀, any other combination is amenable.

With reference to FIGS. 9A-9C, various views 900A-900C of some alternative embodiments of the integrated chip of FIGS. 2A and 2B are provided in which the QFP structure 104 is electrically coupled directly to the drain electrode 114 by the interconnect structure 136. FIG. 9C corresponds to a top layout view 900C, whereas FIG. 9A corresponds to a cross-sectional view 900A along line A-A′ in FIG. 9C and FIG. 9B corresponds to a cross-sectional view 900B along line D-D′ in FIG. 9C. The plurality of first-level QFPs 122₁₁ are directly electrically coupled to the drain electrode 114 by individual ones of the vias 140. As such, one of the vias 140 extends from each of the plurality of first-level QFPs 122₁₁ to the drain electrode 114. Further, during use of the semiconductor device 102, the plurality of first-level QFPs 122₁₁ are biased with a same voltage (e.g., V_{d}) as at the drain electrode 114.

With reference to FIG. 10, a top layout view 1000 of some alternative embodiments of the integrated chip of FIGS. 9A-9C is provided. The plurality of first-level QFPs 122₁₁ are divided into a first subset and a second subset. QFPs of the first subset alternate with QFPs in the second subset and are directly electrically coupled to the drain electrode 114 as in FIGS. 9A-9C. Hence, the QFPs of the first subset are biased at a voltage (e.g., V_{d}) at the drain electrode 114. QFPs of the second subset are not directly electrically coupled to the drain electrode 114 and are separated from the voltage at the drain electrode 114. Instead, the QFPs of the second subset are capacitively coupled to the drain electrode 114 as in FIGS. 2A and 2B.

With reference to FIGS. 11A-11C, various views 1100A-1100C of some alternative embodiments of the integrated chip of FIGS. 9A-9C are provided in which the QFP structure 104 is at a second level that is level with the first SFP 204. Hence, the QFP structure 104 comprises a plurality of second-level QFPs 122₁₂ in place of the plurality of first-level QFPs 122₁₁.

With reference to FIG. 12, a top layout view 1200 of some alternative embodiments of the integrated chip of FIGS. 11A-11C is provided. Some of the plurality of second-level QFPs 122₁₂ are directly electrically coupled to the drain electrode 114 as in FIGS. 11A-11C. Further, some of the plurality of second-level QFPs 122₁₂ are capacitively coupled, instead of directly electrically coupled, to the drain electrode 114 as in FIG. 4A.

With reference to FIGS. 13A-13C, various views 1300A-1300C of some alternative embodiments of the integrated chip of FIGS. 9A-9C are provided in which the QFP structure 104 is at a third level that is level with the second SFP 206. Hence, the QFP structure 104 comprises a plurality of third-level QFPs 122₁₃ in place of the plurality of first-level QFPs 122₁₁. Further, the QFP structure 104 is integrated into one of the wires 138.

With reference to FIG. 14, a top layout view 1400 of some alternative embodiments of the integrated chip of FIGS. 13A-13C is provided. Some of the plurality of third-level QFPs 122₁₃ are directly electrically coupled to the drain electrode 114 as in FIGS. 13A-13C. Further, some of the plurality of third-level QFPs 122₁₃ are capacitively coupled, instead of directly electrically coupled, to the drain electrode 114 as in FIG. 4B.

With reference to FIGS. 15A-15C, various views 1500A-1500C of some alternative embodiments of the integrated chip of FIGS. 9A-9C are provided in which the QFP structure 104 is at a zeroth level that is level with the drain electrode 114. Hence, the QFP structure 104 comprises a plurality of zeroth-level QFPs 122₁₀ in place of the plurality of first-level QFPs 122₁₁. Further, the QFP structure 104 is integrated into the drain electrode 114.

With reference to FIG. 16, a top layout view 1600 of some alternative embodiments of the integrated chip of FIGS. 15A-15C is provided. Some of the plurality of zeroth-level QFPs 122₁₀ are directly electrically coupled to the drain electrode 114 as in FIGS. 15A-15C. Some of the plurality of zeroth-level QFPs 122₁₀ are capacitively coupled, instead of directly electrically coupled, to the drain electrode 114, as in FIG. 4C.

With reference to FIGS. 17A-17C, various views 1700A-1700C of some alternative embodiments of the integrated chip of FIGS. 9A-9C are provided in which the QFP structure 104 spans multiple levels with overlapping QFPs. The QFP structure 104 comprises a plurality of first-level QFPs 122₁₁ and a plurality of second-level QFPs 122₁₂ grouped into a plurality of QFP groups 502, which are directly electrically coupled to the drain electrode 114. The plurality of QFP groups 502 may, for example, be as described with regard to FIGS. 5A-5C other than being directly electrically coupled to the drain electrode 114. In alternative embodiments, the QFP groups 502 may be as in any of FIGS. 6A-6G.

With reference to FIG. 18, a top layout view 1800 of some alternative embodiments of the integrated chip of FIGS. 17A-17C is provided. Some of the QFP groups 502 are directly electrically coupled to the drain electrode 114 as in FIGS. 17A-17C. Some of the QFP groups 502 are capacitively coupled, instead of directly electrically coupled, to the drain electrode 114 as in FIGS. 5A-5C.

With reference to FIGS. 19A-19D, various views 1900A-1900D of some alternative embodiments of the integrated chip of FIGS. 9A-9C are provided in which the QFP structure 104 spans multiple levels with non-overlapping QFPs. FIG. 19D corresponds to a top layout view 1900D, whereas FIG. 19A corresponds to a cross-sectional view 1900A along line A-A′ in FIG. 19D, FIG. 19B corresponds to a cross-sectional view 1900B along line C-C′ in FIG. 19B, and FIG. 19C corresponds to a cross-sectional view 1900C along line D-D′ in FIG. 19C.

The QFP structure 104 comprises a plurality of first-level QFPs 122₁₁ and a plurality of second-level QFPs 122₁₂ that are directly electrically coupled to the drain electrode 114. The plurality of first-level QFPs 122₁₁ overlap with the junction between the active region 106a and the isolation structure 108 at ends of the line defined by QFPs of the QFP structure 104. The plurality of second-level QFPs 122₁₂ fill in a remainder of the QFP structure 104 between the ends of the line defined by the QFPs of the QFP structure 104.

With reference to FIG. 20, a top layout view 2000 of some alternative embodiments of the integrated chip of FIGS. 19A-19D is provided. Some of the plurality of second-level QFPs 122₁₂ are directly electrically coupled to the drain electrode 114 as in FIGS. 19A-19D. Some of the plurality of second-level QFPs 122₁₂ are capacitively coupled, instead of directly electrically coupled, to the drain electrode 114 as in FIG. 4B.

With reference to FIGS. 21A-21C, cross-sectional views 2100A-2100C of some alternative embodiments of the integrated chip of FIGS. 2A and 2B are provided in which the GFP 202 and one or both of the first and second SFPs 204, 206 are respectively omitted. In FIG. 21A, the GFP 202 is omitted. In FIG. 21B the first SFP 204 is omitted. In FIG. 21C, the first SFP 204 and the second SFP 206 are omitted.

With reference to FIGS. 22A and 22B, various views 2200A, 2200B of some alternative embodiments of the integrated chip of FIGS. 2A and 2B are provided in which the semiconductor device 102 is symmetrical. As such, the GFP 202, the first SFP 204, and the second SFP 206 are omitted. Further, an additional QFP structure 104′ is between the source electrode 112 and the gate electrode 118. The symmetry of the semiconductor device 102 allows enhanced performance during both forward and reverse operation.

The additional QFP structure 104′ is as the QFP structure 104 is described and is separated from the source electrode 112 by a separation S1′. The separation S1′ is such that the additional QFP structure 104′ capacitively couples to the source electrode 112. The separation S1′ may, for example, be the same as the separation S1 between the QFP structure 104 and the drain electrode 114 and/or may, for example, be as the separation S1 is described above (e.g., with regard to FIGS. 1A and 1B). In alternative embodiments, the additional QFP structure 104′ directly electrically couples to the source electrode 112.

With reference to FIGS. 23A-23C, cross-sectional views 2300A-2300C of some alternative embodiments of the integrated chip of FIGS. 2A and 2B are provided in which the integrated chip includes an etch stop layer.

In FIG. 23A, a first etch stop layer 2302 separates the ILD layer 208 from the first IMD layer 210, and a second etch stop layer 2304 separates the first IMD layer 210 from the second IMD layer 212. The first etch stop layer 2302 and the second etch stop layer 2304 are different materials than the ILD layer 208, the first IMD layer 210, and the second IMD layer 212. For example, the first etch stop layer 2302 and the second etch stop layer 2304 may, for example, be or comprise silicon nitride and/or silicon carbide, whereas the ILD layer 208, the first IMD layer 210, and the second IMD layer 212 may, for example, be oxide or the like. Other suitable materials are, however, amenable in alternative embodiments.

In FIG. 23B, the source electrode 112 and the drain electrode 114 further have T-shaped profiles. As such, the source and drain electrodes 112, 114 overlie the ILD layer 208.

In FIG. 23C, the source electrode 112 and the drain electrode 114 are further integrated into corresponding ones of the plurality of vias 140. In other words, vias of the plurality of vias 140 form the source electrode 112 and the drain electrode 114.

With reference to FIGS. 24A and 24B to FIGS. 37A and 37B, a series of views of some embodiments of a method for forming an integrated chip comprising a semiconductor device with a QFP structure is provided. Figures labeled with a suffix of “B” correspond to top views, whereas figures labeled with a suffix of “A” correspond to cross-sectional views along line A-A′ in like numbered figures labeled with a suffix of “B”. The integrated chip may, for example, correspond to embodiments of the integrated chip described with regard to FIG. 23A.

As illustrated by views 2400A, 2400B of FIGS. 24A and 24B, a semiconductor film 106 is deposited over a substrate 134. The semiconductor film 106 comprises a channel layer 128, a barrier layer 130, and a buffer layer 132. Individual layers of the semiconductor film 106 may, for example, be sequentially deposited by metal organic chemical vapor deposition (MOCVD) and/or by some other suitable deposition process.

The channel layer 128 underlies and directly contacts the barrier layer 130 at a heterojunction. The barrier layer 130 is polarized so as to induce formation of a 2DCG 110 in the channel layer 128. The buffer layer 132 comprises a buffer nucleation layer 214, a graded buffer layer 216, a super lattice buffer layer 218, and a high resistivity buffer layer 220 stacked between the substrate 134 and the channel layer 128. In alternative embodiments, the buffer nucleation layer 214, the graded buffer layer 216, the super lattice buffer layer 218, the high resistivity buffer layer 220, or any one or more of the foregoing layers is/are omitted.

As illustrated by views 2500A, 2500B of FIGS. 25A and 25B, a cap layer 1161 is deposited over the semiconductor film 106. The cap layer 1161 is a semiconductor layer and is polarized similar to the barrier layer 130 so as to deplete the 2DCG 110 (see, e.g., FIGS. 24A and 24B) directly under the cap layer 1161. The cap layer 1161 may, for example, be deposited by MOCVD and/or by some other suitable deposition process.

In some embodiments, the buffer nucleation layer 214 is or comprise aluminum nitride (e.g., AlN), the graded buffer layer 216 is or comprises aluminum gallium nitride (e.g., AlGaN) with graded aluminum and gallium, the super lattice buffer layer 218 is or comprises an alternating stack of aluminum nitride (e.g., AlN) and gallium nitride (e.g., GaN), the high resistivity buffer layer 220 is or comprises carbon or iron doped gallium nitride (e.g., GaN:C or GaN:Fe), the channel layer 128 is or comprises undoped gallium nitride (e.g., u-GaN), the barrier layer 130 is or comprises aluminum gallium nitride (e.g., AlGaN), and the cap layer 1161 is or comprises p-doped gallium nitride (e.g., p-GaN). Other suitable materials for any one or combination of the foregoing layers and/or structures is/are, however, amenable.

As illustrated by views 2600A, 2600B of FIGS. 26A and 26B, the cap layer 1161 is patterned to form a cap structure 116 localized to a gate region of the semiconductor device being formed. The 2DCG 110 reforms at sides of the cap structure (e.g., where the cap layer 1161 is removed), and a depletion region 120 underlies the cap structure 116. The patterning may, for example, be performed by a photolithography/etching process and/or by some other suitable patterning process.

Also illustrated by the views 2600A, 2600B of FIGS. 26A and 26B, an ILD layer 208 is deposited covering the cap structure 116. In some embodiments, a planarization is further performed into a top surface of the ILD layer 208 to flatten the top surface. The planarization may, for example, be performed by a chemical mechanical polish (CMP) and/or the like.

As illustrated by views 2700A, 2700B of FIGS. 27A and 27B, a source electrode 112 and a drain electrode 114 are formed inset into the ILD layer 208, respectively on opposite sides of the cap structure 116. In some embodiments, the source and drain electrodes 112, 114 are formed ohmically electrically coupled to the 2DCG 110.

A process for forming the source electrode 112 and the drain electrode 114 may, for example, comprise: 1) patterning the ILD layer 208 to form a source opening and a drain opening in the ILD layer 208; 2) depositing a conductive layer overlying the ILD layer 208 and filling the source and drain openings; and 3) performing a planarization into the conductive layer to level a top surface of the conductive layer with a top surface of the ILD layer 208. Other suitable processes are, however, amenable. The patterning may, for example, be performed by a photolithography/etching process and/or by some other suitable patterning process. The planarization may, for example, be performed by a CMP and/or the like.

As illustrated by views 2800A, 2800B of FIGS. 28A and 28B, the ILD layer 208 is extended to cover the source and drain electrodes 112, 114 and the cap structure 116. As such, the ILD layer 208 has a lower portion 2081 and an upper portion 208u that is newly formed to cover the source and drain electrodes 112, 114 and the cap structure 116. The ILD layer 208 may, for example, be extended by depositing additional dielectric material of the ILD layer 208 overlying the source and drain electrodes 112, 114 and the cap structure 116.

As illustrated by views 2900A, 2900B of FIGS. 29A and 29B, oxygen 2902 is implanted into the semiconductor film 106 to form an isolation structure 108 surrounding and demarcating an active region 106a of the semiconductor film 106. The active region 106a underlies the source electrode 112, the drain electrode 114, and the cap structure 116. The implantation forms the isolation structure 108 in the channel layer 128 and the barrier layer 130 and is performed through the ILD layer 208.

In some embodiments, the implantation is performed by ion implantation, such that the oxygen 2902 may more specifically correspond to oxygen ions. Other suitable processes for performing the implantation are, however, amenable. Further, in some embodiments, the implantation is performed with a mask 2904 in place and the mask 2904 is removed after the implantation. The mask 2904 may, for example, be or comprise a photoresist mask, a hard mask, the like, or any combination of the foregoing.

As illustrated by views 3000A, 3000B of FIGS. 30A and 30B, a first etch stop layer 2302 is deposited covering the ILD layer 208. The first etch stop layer 2302 is a different material type than the ILD layer 208. For example, the first etch stop layer 2302 may be or comprise silicon nitride and/or silicon carbide, whereas the ILD layer 208 may, for example, be or compromise an oxide. Other suitable materials are, however, amenable.

As illustrated by views 3100A, 3100B of FIGS. 31A and 31B, the first etch stop layer 2302 and the ILD layer 208 are patterned to form a gate opening 3102 exposing the cap structure 116. The patterning may, for example, be performed by a photolithography/etching process and/or by some other suitable patterning process.

As illustrated by views 3200A, 3200B of FIGS. 32A and 32B, a conductive layer 3202 is deposited covering the first etch stop layer 2302 and filling the gate opening 3102.

As illustrated by views 3300A, 3300B of FIGS. 33A and 33B, the conductive layer 3202 is patterned to form a gate electrode 118 integrated with a GFP 202 and to further form a QFP structure 104. The patterning may, for example, be performed by a photolithography/etching process and/or by some other suitable patterning process. In alternative embodiments, the GFP 202 is omitted and hence not formed.

The GFP 202 overlies the first etch stop layer 2302 and protrudes from a drain side of the gate electrode 118 laterally towards the drain electrode 114. The QFP structure 104 overlies the first etch stop layer 2302, level with the GFP 202, and is laterally between the GFP 202 and the drain electrode 114. The QFP structure 104 comprises a plurality of first-level QFPs 122₁₁. The plurality of first-level QFPs 122₁₁ are spaced in a line across the active region 106a in a direction orthogonal or otherwise transverse to a direction along which the source electrode 112 and the drain electrode 114 are spaced from each other. Further, the plurality of first-level QFPs 122₁₁ are capacitively coupled to the drain electrode 114.

The gate electrode 118, the source electrode 112, and the drain electrode 114, and so on form a semiconductor device 102. During use of the semiconductor device 102, the QFP structure 104 is biased with a voltage that is proportional to a voltage at the drain electrode 114 via capacitive coupling between the QFP structure 104 and the drain electrode 114. In alternative embodiments, the QFP structure 104 is formed directly electrically coupled to the drain electrode 114. The biasing attracts carriers 125 of a same type as carriers of the 2DCG 110 to the 2DCG 110. For example, when the 2DCG 110 is a 2DEG, the QFP structure 104 attracts electrons. As another example, when the 2DCG 110 is a 2DHG, the QFP structure 104 attracts holes. The attracted carriers 125 increase conductivity of the 2DCG 110 and have been appreciated to increase conductivity uniformity of the 2DCG 110.

As an example, attention is directed to FIG. 33B. The 2DCG 110 may have a lower conductivity at a junction 126 between the active region 106a and the isolation structure 108 than at surrounding regions of the 2DCG 110. By arranging QFPs of the QFP structure 104 (e.g., QFPs at ends of the line) overlapping with the junction 126, conductivity of the 2DCG 110 may be increased at the junction 126 and may more closely match the conductivity of the 2DCG 110 at the surrounding regions. Hence, conductivity uniformity may be increased.

Because the QFP structure 104 increases conductivity of the 2DCG 110, the QFP structure 104 reduces ON resistance of the semiconductor device 102. Because the QFP structure 104 increases conductivity uniformity, the QFP structure 104 increases electric field uniformity of the semiconductor device 102. Because electric field uniformity may be increased, threshold voltage and a peak electric field may be decreased. Because the peak electric field may be decreased, breakdown voltage and reliability may be increased and OFF-state leakage may be decreased. Because uniformity of the 2DCG 110 and the electric field may be increased, wafer uniformity and manufacturing yields may be increased. It has been appreciated that this increase in wafer uniformity may be sufficient to counteract any decrease in wafer uniformity from, for example, process variation, epitaxial variation, and the like.

Because the QFP structure 104 is formed with the gate electrode 118, the QFP structure 104 may add little cost. Further, because the QFP structure 104 spans a relatively small area, the QFP structure 104 may not increase a size of the semiconductor device 102.

In some embodiments, the plurality of first-level QFPs 122₁₁ are or comprises nickel, gold, platinum, iridium, titanium nitride, aluminum copper, palladium, some other suitable metal(s) and/or metallic material(s), or any combination of the foregoing. While the QFP structure 104 is illustrated with seven QFPs, the QFP structure 104 may alternatively have 10-1000 QFPs, about 10-505 QFPs, about 505-1000 QFPs, or some other suitable number of QFPs. For example, the QFP structure 104 may alternatively have 10 or 100 QFPs. It has been appreciated that multiple small QFPs in a line, instead of a single large QFP, is more effective at enhancing performance and wafer uniformity of the semiconductor device 102.

As illustrated by views 3400A, 3400B of FIGS. 34A and 34B, a first IMD layer 210 is deposited over the gate electrode 118 and the QFP structure 104, and thereafter a second etch stop layer 2304 is deposited over the first IMD layer 210. In some embodiments, a planarization is performed into a top surface of the first IMD layer 210 to flatten the top surface before the depositing of the second etch stop layer 2304. The planarization may, for example, be performed by a CMP and/or the like. The second etch stop layer 2304 is a different material type as the first IMD layer 210. For example, the second etch stop layer 2304 may, for example, be or comprise silicon nitride and/or silicon carbide, whereas the first IMD layer 210 may, for example, be or compromise an oxide. Other suitable materials are, however, amenable.

As illustrated by views 3500A, 3500B of FIGS. 35A and 35B, a first SFP 204 is formed overlying the second etch stop layer 2304. The first SFP 204 has a drain side that is laterally closer to the drain electrode 114 than a drain side of the GFP 202. A process for forming the first SFP 204 may, for example, comprise: 1) depositing a conductive layer overlying the second etch stop layer 2304; and 2) patterning the conductive layer into the first SFP 204. The patterning may, for example, be performed by a photolithography/etching process and/or by some other suitable patterning process.

As illustrated by views 3600A, 3600B of FIGS. 36A and 36B, a second IMD layer 212 is deposited overlying the second etch stop layer 2304 and the first SFP 204. In some embodiments, a planarization is further performed into a top surface of the second IMD layer 212 to flatten the top surface. The planarization may, for example, be performed by a CMP and/or the like.

As illustrated by views 3700A, 3700B of FIGS. 37A and 37B, an interconnect structure 136 is formed overlying and electrically coupled to the semiconductor device 102. The interconnect structure 136 comprises a plurality of wires 138 and a plurality of vias 140 stacked in the ILD layer 208, the first IMD layer 210, and the second IMD layer 212. Further, one of the plurality of wires 138 overlies the first SFP 204 and forms a second SFP 206 with a drain side that is laterally closer to the drain electrode 114 than a drain side of the first SFP 204.

While FIGS. 24A and 24B to FIGS. 37A and 37B are described with reference to a method, it will be appreciated that the structures shown in these figures are not limited to the method but rather may stand alone separate of the method. While FIGS. 24A and 24B to FIGS. 37A and 37B are described as a series of acts, it will be appreciated that the order of the acts may be altered in other embodiments. While FIGS. 24A and 24B to FIGS. 37A and 37B illustrate and describe as a specific set of acts, some acts that are illustrated and/or described may be omitted in other embodiments. Further, acts that are not illustrated and/or described may be included in other embodiments.

With reference to FIG. 38, a block diagram 3800 of some embodiments of the method of FIGS. 24A and 24B to FIGS. 37A and 37B is provided.

At 3802, a channel layer and a barrier layer are deposited stacked on a substrate, wherein the channel layer accommodates a 2DCG. See, for example, FIGS. 24A and 24B.

At 3804, a cap structure is formed overlying the channel layer and the barrier layer. See, for example, FIGS. 25A and 25B to FIGS. 26A and 26B.

At 3806, an ILD layer is deposited overlying the cap structure. See, for example, FIGS. 26A and 26B.

At 3808, a source electrode and a drain electrode are formed respectively on opposite sides of the cap structure and inset into the ILD layer. See, for example, FIGS. 27A and 27B.

At 3810, an isolation structure is formed surrounding and demarcating an active region on which the cap structure, the source electrode, and the drain electrode are arranged. See, for example, FIGS. 28A and 28B to FIGS. 29A and 29B.

At 3812, a gate electrode is formed extending through the ILD layer to the cap structure. See, for example, FIGS. 30A and 30B to FIGS. 33A and 33B.

At 3814, a plurality of QFPs are formed overlying the ILD layer and spaced in a line, laterally between the gate electrode and the drain electrode. See, for example, FIGS. 30A and 30B to FIGS. 33A and 33B.

At 3816, a first IMD layer is deposited overlying the gate electrode and the plurality of QFPs. See, for example, FIGS. 34A and 34B.

At 3818, a first SFP is formed overlying the first IMD layer. See, for example, FIGS. 35A and 35B.

At 3820, a second IMD layer is deposited overlying the first SFP. See, for example, FIGS. 36A and 36B.

At 3822, an interconnect structure is formed electrically coupled to the source electrode and the drain electrode and in the ILD layer, the first IMD layer, and the second IMD layer, wherein a wire of the interconnect structure forms a second SFP overlying the second IMD layer. See, for example, FIGS. 37A and 37B.

While the block diagram 3800 of FIG. 38 is illustrated and described herein as a series of acts or events, it will be appreciated that the illustrated ordering of such acts or events is not to be interpreted in a limiting sense. For example, some acts may occur in different orders and/or concurrently with other acts or events apart from those illustrated and/or described herein. Further, not all illustrated acts may be required to implement one or more aspects or embodiments of the description herein, and one or more of the acts depicted herein may be carried out in one or more separate acts and/or phases.

With reference to FIGS. 39A and 39B to FIGS. 42A and 42B, a series of views of some alternative embodiments of the method of FIGS. 24A and 24B to FIGS. 37A and 37B is provided in which the QFP structure 104 is formed level with the cap structure 116. Figures labeled with a suffix of “B” correspond to top views, whereas figures labeled with a suffix of “A” correspond to cross-sectional views along line A-A′ in like numbered figures labeled with a suffix of “B”.

As illustrated by views 3900A, 3900B of FIGS. 39A and 39B, the acts described with regard to FIGS. 24A and 24B to FIGS. 29A and 29B are performed as described above. Further, after these acts are completed, the ILD layer 208 is patterned to form a plurality of QFP openings 3902 spaced in a line laterally between the cap structure 116 and the drain electrode 114. The patterning may, for example, be performed by a photolithography/etching process and/or by some other suitable patterning process.

As illustrated by views 4000A, 4000B of FIGS. 40A and 40B, a conductive layer 4002 is deposited covering the ILD layer 208 and filling the plurality of QFP openings 3902.

As illustrated by views 4100A, 4100B of FIGS. 41A and 41B, a planarization is performed into the conductive layer 4002. The planarization extends to a top surface of the ILD layer 208 and forms a plurality of zeroth-level QFPs 122₁₀ respectively in the plurality of QFP openings 3902. The plurality of zeroth-level QFPs 122₁₀ form a QFP structure 104 as described with regard to, for example, FIGS. 33A and 33B, except that the QFP structure 104 is level with the cap structure 116 rather than being elevated above the cap structure.

As illustrated by views 4200A, 4200B of FIGS. 42A and 42B, the acts described with regard to FIGS. 30A and 30B to FIGS. 37A and 37B are performed as described above, except that the QFP structure 104 is not formed during the acts of FIGS. 33A and 33B. The QFP structure 104 has already been formed by the time the acts of FIGS. 33A and 33B are performed.

With reference to FIGS. 43A and 43B to FIGS. 45A and 45B, a series of views of some alternative embodiments of the method of FIGS. 24A and 24B to FIGS. 37A and 37B is provided in which the isolation structure 108 is formed before the cap structure 116. Figures labeled with a suffix of “B” correspond to top views, whereas figures labeled with a suffix of “A” correspond to cross-sectional views along line A-A′ in like numbered figures labeled with a suffix of “B”.

As illustrated by views 4300A, 4300B of FIGS. 43A and 43B, the acts described with regard to FIGS. 24A and 24B are performed as described above. Further, the channel layer 128 and the barrier layer 130 are patterned to form a trench 4302 surrounding and demarcating an active region 106a of the semiconductor film 106. The patterning may, for example, be performed by a photolithography/etching process and/or by some other suitable patterning process.

As illustrated by views 4400A, 4400B of FIGS. 44A and 44B, the trench 4302 is filled with a dielectric material to form an isolation structure 108 surrounding and demarcating the active region 106a. The filling may, for example, be performed by depositing a dielectric layer filling the trench 4302 and covering the barrier layer 130 and then performing a planarization into the dielectric layer to uncover the barrier layer 130. Other suitable processes are, however, amenable in alternative embodiments.

As illustrated by views 4500A, 4500B of FIGS. 45A and 45B, the acts described with regard to FIGS. 25A and 25B to FIGS. 28A and 28B and FIGS. 30A and 30B to 37A and 37B are performed as described above. Notably, the acts described with regard to FIGS. 29A and 29B are skipped since the isolation structure 108 has already been formed by the time the acts of FIGS. 29A and 29B would be performed. Further, the source electrode 112 and the drain electrode 114 are formed overlapping with the isolation structure 108. The overlap may, for example, be achieved by expanding a mask used to form the source electrode 112 and the drain electrode 114 during the acts of FIGS. 27A and 27B.

With reference to FIGS. 46A and 46B to FIGS. 49A and 49B, a series of views of some alternative embodiments of the method of FIGS. 24A and 24B to FIGS. 37A and 37B is provided in which the source electrode 112 and the drain electrode overlie the ILD layer 208. Figures labeled with a suffix of “B” correspond to top views, whereas figures labeled with a suffix of “A” correspond to cross-sectional views along line A-A′ in like numbered figures labeled with a suffix of “B”.

As illustrated by views 4600A, 4600B of FIGS. 46A and 46B, the acts described with regard to FIGS. 24A and 24B to FIGS. 26A and 26B are performed as described above, except that a planarization exposes a top surface of the cap structure 116. The planarization may, for example, also be performed to flatten a top surface of the ILD layer 208. In alternative embodiments, the planarization stops before exposing the cap structure 116, such that the cap structure remains covered by the ILD layer 208. The planarization may, for example, be performed by a CMP and/or the like.

Also illustrated by the views 4600A, 4600B of FIGS. 46A and 46B, a source electrode 112 and a drain electrode 114 are formed. The source electrode 112 and the drain electrode 114 are formed respectively on opposite sides of the cap structure 116 and are formed with T-shaped profiles. Other suitable profiles are, however, amenable.

A process for forming the source electrode 112 and the drain electrode 114 may, for example, comprise: 1) patterning the ILD layer 208 to form a source opening and a drain opening in the ILD layer 208; 2) depositing a conductive layer overlying the ILD layer 208 and filling the source and drain openings; and 3) patterning the conductive layer into the source and drain electrodes 112, 114. Other suitable processes are, however, amenable. The patterning may, for example, be performed by a photolithography/etching process and/or by some other suitable patterning process.

As illustrated by views 4700A, 4700B of FIGS. 47A and 47B, a first etch stop layer 2302 is deposited covering the ILD layer 208 and the source and drain electrodes 112, 114. The first etch stop layer 2302 is a different material type than the ILD layer 208.

As illustrated by views 4800A, 4800B of FIGS. 48A and 48B, oxygen 2902 is implanted into the semiconductor film 106 to form an isolation structure 108. The implantation is performed as described with regard to FIGS. 29A and 29B, except that the implantation is performed through both the ILD layer 208 and the first etch stop layer 2302. In alternative embodiments, the implantation is performed between the forming of the source electrode 112 and the drain electrode 114 at FIGS. 46A and 46B and the depositing of the first etch stop layer 2302 at FIGS. 47A and 47B. In such alternative embodiments, the implantation would be performed through the ILD layer 208, but not through the first etch stop layer 2302.

As illustrated by views 4900A, 4900B of FIGS. 49A and 49B, the acts described with regard to FIGS. 31A and 31B to FIGS. 37A and 37B are performed as described above.

While FIGS. 39A and 39B to FIGS. 49A and 49B are described with reference to a method, it will be appreciated that the structures shown in these figures are not limited to the method but rather may stand alone separate of the method. While FIGS. 39A and 39B to FIGS. 49A and 49B are described as a series of acts, it will be appreciated that the order of the acts may be altered in other embodiments. While FIGS. 39A and 39B to FIGS. 49A and 49B illustrate and describe as a specific set of acts, some acts that are illustrated and/or described may be omitted in other embodiments. Further, acts that are not illustrated and/or described may be included in other embodiments.

In some embodiments, the present disclosure provides a semiconductor device, including: a substrate; a channel layer and a barrier layer stacked on the substrate, wherein the channel layer accommodates a 2DCG; a source electrode, a drain electrode, and a gate electrode overlying the channel layer and the barrier layer, wherein the gate electrode is between the source electrode and the drain electrode in a first direction; and a plurality of field plates between the gate electrode and the drain electrode, wherein the plurality of field plates are spaced from the gate electrode and are spaced from each other in a line extending in a second direction transverse to the first direction. In some embodiments, the plurality of field plates include a first field plate that is capacitively coupled to the drain electrode. In some embodiments, the plurality of field plates include a first field plate that is directly electrically coupled to the drain electrode. In some embodiments, the plurality of field plates include a first field plate level with the gate electrode. In some embodiments, the semiconductor device further includes a cap structure separating the gate electrode from the channel layer and the barrier layer, wherein the plurality of field plates include a first field plate level with the cap structure. In some embodiments, the semiconductor device further includes: a wire overlying the source electrode; and a via extending from the wire to the source electrode; wherein the plurality of field plates include a first field plate level with and spaced from the wire. In some embodiments, the semiconductor device further includes: a wire overlying the source electrode; and a via extending from the wire to the source electrode; wherein the plurality of field plates include a field first plate recessed relative to the wire and elevated relative to the gate electrode. In some embodiments, the semiconductor device further includes a plurality of additional field plates between the gate electrode and the source electrode, wherein the plurality of additional field plates are spaced from each other in an additional line extending in the second direction and are closer to the source electrode than the gate electrode.

In some embodiments, the present disclosure provides an integrated chip, including: a semiconductor substrate; a group III-V heterojunction structure on the semiconductor substrate; an isolation structure in the group III-V heterojunction structure, wherein the isolation structure surrounds and demarcates an active region of the group III-V heterojunction structure; a source electrode, a drain electrode, and a gate electrode overlying the group III-V heterojunction structure with the gate electrode between the source and drain electrodes; and a plurality of field plates between the gate electrode and the drain electrode and spaced from each other from a first side of the active region to a second side of the active region opposite the first side, wherein the plurality of field plates includes a first field plate overlapping with a junction between the isolation structure and the active region. In some embodiments, the plurality of field plates are closer to the drain electrode than to than to the gate electrode. In some embodiments, the plurality of field plates alternate between multiple different elevations from the first side of the active region to the second side of the active region. In some embodiments, the plurality of field plates include a first subset of field plates at a first elevation and a second subset of field plates at a second elevation above the first elevation, wherein the plurality of field plates define a plurality of field plate groups spaced from each other in a line from the first side of the active region to the second side of the active region, and wherein each of the plurality of field plate groups includes a field plate of the first subset and a field plate of the second subset overlapping with the field plate of the first subset. In some embodiments, the integrated chip further includes a plurality of additional field plates between the gate electrode and the source electrode, wherein the plurality of additional field plates are in a row spanning an entire width of the active region and are closer to the source electrode than the gate electrode. In some embodiments, the source electrode, the drain electrode, the gate electrode, and the plurality of field plates define a semiconductor device and are spaced from each other in a cross-sectional plane, wherein the semiconductor device is symmetrical in the cross-sectional plane. In some embodiments, the integrated chip further includes a GFP integrated with the gate electrode and protruding from a top of the gate electrode laterally towards the drain electrode.

In some embodiments, the present disclosure provides a method including: forming a channel layer and a barrier layer stacked on a substrate, wherein the channel layer accommodates a 2DCG; forming a cap structure overlying the channel and barrier layers; forming a source electrode and a drain electrode overlying the channel and barrier layers, respectively on opposite sides of the cap structure; forming a gate electrode atop the cap structure; and forming a plurality of field plates laterally between the gate electrode and the drain electrode, wherein the plurality of field plates are spaced from the gate electrode in a direction and are spaced from each other laterally in a line extending orthogonal to the direction. In some embodiments, the method further includes: depositing a dielectric layer overlying the cap structure; performing a first etch into the dielectric layer to form an opening exposing the cap structure; depositing a conductive layer overlying the dielectric layer and filling the opening; and performing a second etch into the conductive layer to form the gate electrode and the plurality of field plates. In some embodiments, the second etch further forms a GFP integrated with and protruding from a top of the gate electrode, wherein the plurality of field plates are between the GFP and the drain electrode. In some embodiments, the method further includes: depositing a dielectric layer overlying the cap structure; performing a first etch into the dielectric layer to form a plurality of openings between the cap structure and the drain electrode; forming the plurality of field plates respectively in the plurality of openings; and forming the gate electrode after the forming of the plurality of field plates. In some embodiments, the method further includes: depositing a dielectric layer overlying the cap structure; and selectively implanting oxygen into the channel layer and the barrier layer through the dielectric layer to form an isolation structure surrounding and demarcating an active region individual to a semiconductor device defined by the source and drain electrodes and the gate electrode.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a channel layer and a barrier layer stacked on the substrate, wherein the channel layer accommodates a two-dimensional carrier gas (2DCG);
a source electrode, a drain electrode, and a gate electrode overlying the channel layer and the barrier layer, wherein the gate electrode is between the source electrode and the drain electrode in a first direction; and
a plurality of field plates between the gate electrode and the drain electrode, wherein the plurality of field plates are spaced from the gate electrode and are spaced from each other in a line extending laterally in a second direction transverse to the first direction.

2. The semiconductor device according to claim 1, wherein the plurality of field plates comprise a first field plate that is capacitively coupled to the drain electrode.

3. The semiconductor device according to claim 1, wherein the plurality of field plates comprise a first field plate that is directly electrically coupled to the drain electrode.

4. The semiconductor device according to claim 1, wherein the plurality of field plates comprise a first field plate level with the gate electrode.

5. The semiconductor device according to claim 1, further comprising:
a cap structure separating the gate electrode from the channel layer and the barrier layer, wherein the plurality of field plates comprise a first field plate level with the cap structure.

6. The semiconductor device according to claim 1, further comprising:
a wire overlying the source electrode; and
a via extending from the wire to the source electrode;
wherein the plurality of field plates comprise a first field plate level with and spaced from the wire.

7. The semiconductor device according to claim 1, further comprising:
a wire overlying the source electrode; and
a via extending from the wire to the source electrode;
wherein the plurality of field plates comprise a field first plate recessed relative to the wire and elevated relative to the gate electrode.

8. The semiconductor device according to claim 1, further comprising:
a plurality of additional field plates between the gate electrode and the source electrode, wherein the plurality of additional field plates are spaced from each other in an additional line extending in the second direction and are closer to the source electrode than the gate electrode.

9. An integrated chip, comprising:
a semiconductor substrate;
a group III-V heterojunction structure on the semiconductor substrate;
an isolation structure in the group III-V heterojunction structure, wherein the isolation structure surrounds and demarcates an active region of the group III-V heterojunction structure;
a source electrode, a drain electrode, and a gate electrode overlying the group III-V heterojunction structure with the gate electrode between the source and drain electrodes; and
a plurality of field plates between the gate electrode and the drain electrode and spaced from each other from a first side of the active region to a second side of the active region opposite the first side, wherein the plurality of field plates comprises a first field plate overlapping with a junction between the isolation structure and the active region.

10. The integrated chip according to claim 9, wherein the plurality of field plates are closer to the drain electrode than to the gate electrode.

11. The integrated chip according to claim 9, wherein the plurality of field plates alternate between multiple different elevations from the first side of the active region to the second side of the active region.

12. The integrated chip according to claim 9, wherein the plurality of field plates comprise a first subset of field plates at a first elevation and a second subset of field plates at a second elevation above the first elevation, wherein the plurality of field plates define a plurality of field plate groups spaced from each other in a line from the first side of the active region to the second side of the active region, and wherein each of the plurality of field plate groups comprises a field plate of the first subset and a field plate of the second subset overlapping with the field plate of the first subset.

13. The integrated chip according to claim 9, further comprising:
a plurality of additional field plates between the gate electrode and the source electrode, wherein the plurality of additional field plates are in a row spanning an entire width of the active region and are closer to the source electrode than to the gate electrode.

14. The integrated chip according to claim 9, wherein the source electrode, the drain electrode, the gate electrode, and the plurality of field plates define a semiconductor device and are spaced from each other in a cross-sectional plane, and wherein the semiconductor device is symmetrical in the cross-sectional plane.

15. The integrated chip according to claim 9, further comprising:
a gate field plate (GFP) integrated with the gate electrode and protruding from a top of the gate electrode laterally towards the drain electrode.

16. A method comprising:
forming a channel layer and a barrier layer stacked on a substrate, wherein the channel layer accommodates a two-dimensional carrier gas (2DCG);
forming a cap structure overlying the channel and barrier layers;
forming a source electrode and a drain electrode overlying the channel and barrier layers, respectively on opposite sides of the cap structure;
forming a gate electrode atop the cap structure; and
forming a plurality of field plates laterally between the gate electrode and the drain electrode, wherein the plurality of field plates are spaced from the gate electrode in a direction and are spaced from each other laterally in a line extending orthogonal to the direction.

17. The method according to claim 16, further comprising:
depositing a dielectric layer overlying the cap structure;
performing a first etch into the dielectric layer to form an opening exposing the cap structure;
depositing a conductive layer overlying the dielectric layer and filling the opening; and
performing a second etch into the conductive layer to form the gate electrode and the plurality of field plates.

18. The method according to claim 17, wherein the second etch further forms a gate field plate (GFP) integrated with and protruding from a top of the gate electrode, and wherein the plurality of field plates are between the GFP and the drain electrode.

19. The method according to claim 16, further comprising:
depositing a dielectric layer overlying the cap structure;
performing a first etch into the dielectric layer to form a plurality of openings between the cap structure and the drain electrode;
forming the plurality of field plates respectively in the plurality of openings; and
forming the gate electrode after the forming of the plurality of field plates.

20. The method according to claim 16, further comprising:
depositing a dielectric layer overlying the cap structure; and
selectively implanting oxygen into the channel layer and the barrier layer through the dielectric layer to form an isolation structure surrounding and demarcating an active region individual to a semiconductor device defined by the source and drain electrodes and the gate electrode.
